(19) United States
(12) Patent Application Publication
(10) Pub. No.: US 2022/0284140 A1
(43) Pub. Date: Sep. 8, 2022

(54) Systems And Methods For Providing A Virtual Locksmith

(71) Applicant: Curv Brands, LLC, Miami, FL (US)

(72) Inventor: Michael Tunney, Mount Prospect, IL (US)

(21) Appl. No.: 17/582,297

(22) Filed: Jan. 24, 2022

Related U.S. Application Data
(60) Provisional application No. 63/156,814, filed on Mar. 4, 2021.

(51) Int. Cl. G06F 30/10

(52) U.S. Cl. CPC G06F 30/10

(57) ABSTRACT

The disclosed computer-implemented method for providing a virtual locksmith may include (i) receiving, from an individual or entity in possession of an original physical key to a lock, a photograph of the original physical key, (ii) extracting, through analysis of the photograph in software, design specifications for the original physical key that are sufficient for a key generator facility to reproduce the original physical key, and (iii) exporting the design specifications to enable the key generator facility to reproduce the original physical key as a reproduction and deliver the reproduction of the original physical key. Various other methods, systems, and computer-readable media are also disclosed.

### BACKGROUND

Physical locks and corresponding keys are ubiquitous in the modern marketplace. Users of these keys and locks sometimes misplace or lose the keys, which creates an inconvenience. The users may seek to replace the misplaced keys, but current replacement procedures may still present inconveniences for the users. The present disclosure, therefore, identifies and addresses a need for improved systems and methods for providing a virtual locksmith.

### SUMMARY

As will be described in greater detail below, the present disclosure describes various systems and methods for providing a virtual locksmith. In one example, a computer-implemented method for providing a virtual locksmith may include (i) receiving, from an individual or entity in possession of an original physical key to a lock, a photograph of the original physical key, (ii) extracting, through analysis of the photograph in software, design specifications for the original physical key that are sufficient for a key generator facility to reproduce the original physical key, and (iii) exporting the design specifications to enable the key generator facility to reproduce the original physical key as a reproduction and deliver the reproduction of the original physical key.

In one embodiment, the computer-implemented method may further include the key generator facility reproducing the original physical key. In one embodiment, the computer-implemented method may further include the key generator facility delivering the reproduction of the original physical key to the individual or entity.

In one embodiment, extracting, through analysis of the photograph in software, the design specifications includes identifying a type of the original physical key in terms of the head type of the original physical key or a length of the original physical key. In one embodiment, extracting, through analysis of the photograph in software, the design specifications may include identifying a location within a database of key locations where the location holds a preexisting key that corresponds to the original physical key such that the preexisting key can be cut to reproduce the original physical key.

In one embodiment, extracting, through analysis of the photograph in software, the design specifications may include measuring a set of teeth locations along an edge of the original physical key. In one embodiment, the set of teeth locations may include every tooth along the edge of the original physical key. In some examples, measuring the set of teeth locations may include establishing coordinates that locate the respective teeth locations as two-dimensional offsets from a (0, 0) point on a two-dimensional plane. In one embodiment, the two-dimensional offsets from the (0, 0) point on the two-dimensional plane inform a micro mill how to cut the preexisting key when the preexisting key is loaded onto a jig in relation to a (0, 0) point on the jig such that the original physical key is reproduced.

In one embodiment, extracting, through analysis of the photograph in software, the design specifications may include extracting a GM code that identifies a preexisting key that can be cut to create the replacement of the original physical key. In some examples, the computer-implemented method may further include encrypting the GM code. In some examples, the computer-implemented method may further include transmitting the GM code to a tower computer that loads the GM code to enable a micro mill to cut the pre-existing key that matches the GM code.

In some examples, the computer-implemented method may further include displaying the replacement sufficiently adjacent the photograph of the original physical key according to a 1:1 sizing ratio to enable a comparison. In some examples, the computer-implemented method may further include performing a visual inspection to ensure that the replacement sufficiently matches the photograph of the original physical key.

In some examples, the computer-implemented method may further include storing a copy of the design specifications within an encrypted vault to enable the individual or entity to subsequently reuse the design specifications without providing an additional photograph of the original physical key or the replacement. In some examples, performing the method eliminates a requirement for the individual or entity to physically deliver the original physical key to the key generator facility in order to generate the replacement.

In one embodiment, extracting, through analysis of the photograph in software, the design specifications may include identifying a type of the original physical key as a KWIKSET type or SCHLAGE type. In one embodiment, extracting, through analysis of the photograph in software, the design specifications may include identifying a type of the original physical key as a pin tumbler lock key or a wafer tumbler lock key.

In one embodiment, a system for implementing the above-described method may include (i) a reception module, stored in memory, that receives, from an individual or entity in possession of an original physical key to a lock, a photograph of the original physical key, (ii) an extraction module, stored in memory, that extracts, through analysis of the photograph in software, design specifications for the original physical key that are sufficient for a key generator facility to reproduce the original physical key, (iii) an exporting module, stored in memory, that exports the design specifications to enable the key generator facility to reproduce the original physical key as a reproduction and deliver the reproduction of the original physical key, and (iv) at least one physical processor configured to execute the reception module, the extraction module, and the exporting module.

In some examples, the above-described method may be encoded as computer-readable instructions on a non-transitory computer-readable medium. For example, a computer-readable medium may include one or more computer-executable instructions that, when executed by at least one processor of a computing device, may cause the computing device to (i) receive, from an individual or entity in possession of an original physical key to a lock, a photograph of the original physical key, (ii) extract, through analysis of the photograph in software, design specifications for the original physical key that are sufficient for a key generator facility to reproduce the original physical key, and (iii) export the design specifications to enable the key generator facility to reproduce the original physical key as a reproduction and deliver the reproduction of the original physical key.

Features from any of the embodiments described herein may be used in combination with one another in accordance with the general principles described herein. These and other embodiments, features, and advantages will be more fully understood upon reading the following detailed description in conjunction with the accompanying drawings and claims.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a block diagram of an example system for providing a virtual locksmith.

FIG. 2 is a block diagram of an additional example system for providing a virtual locksmith.

FIG. 3 is a flow diagram of an example method for providing a virtual locksmith.

FIG. 4 is a flow diagram of another example method for providing a virtual locksmith.

FIG. 5 is a diagram of an example of categorizing a type of key.

FIG. 6 is a diagram of the bow, shoulder, and blade of a key.

FIG. 7 is a diagram of an inventory of keys that matches a key location database.

FIG. 8 is an example of computer code that facilitates the reproduction of a key.

FIG. 9 is a diagram of a jig on which a replacement key may be cut.

FIG. 10 is a diagram of a micro mill that may be used to cut the key.

FIG. 11 is another diagram with more detail regarding the different parts of the key.

FIG. 12 is a block diagram of an example computing system capable of implementing one or more of the embodiments described and/or illustrated herein.

FIG. 13 is a block diagram of an example computing network capable of implementing one or more of the embodiments described and/or illustrated herein.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE EMBODIMENTS

The present disclosure is generally directed to systems and methods for providing a virtual locksmith. The disclosed technology may overcome problems and inefficiencies associated with related systems for replacing a physical key. In these related systems, an individual or entity would generally be required to physically transport the key to a key replacement facility in order to receive the replacement. In contrast, the technology disclosed herein may enable an individual or organization to simply take a photograph of the key and conveniently transmit the photograph to the key replacement facility. At that point, the key replacement facility may analyze the photograph in software to ascertain specifications for replacing the key. Thus, the disclosed technology may completely eliminate the need for the individual to transport the key to the key replacement facility, thereby greatly increasing the convenience factor for the user. These and other benefits of the disclosed subject matter are discussed in more detail below.

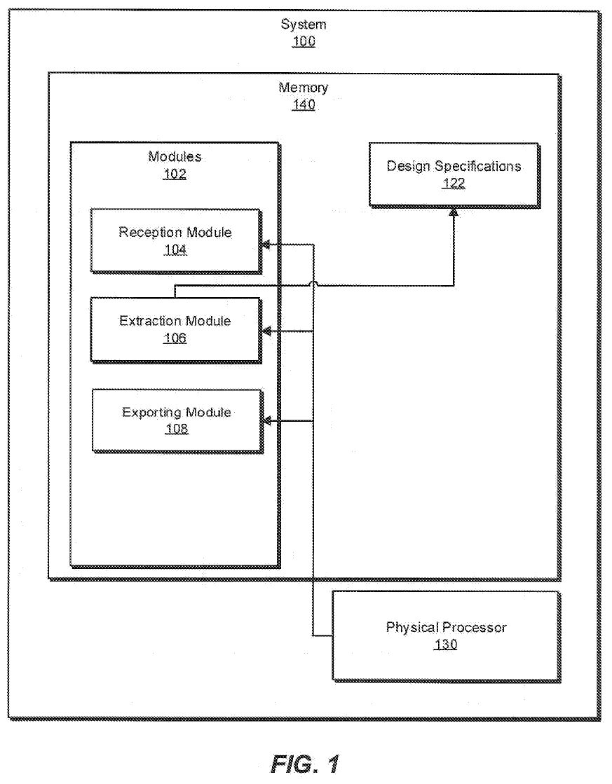

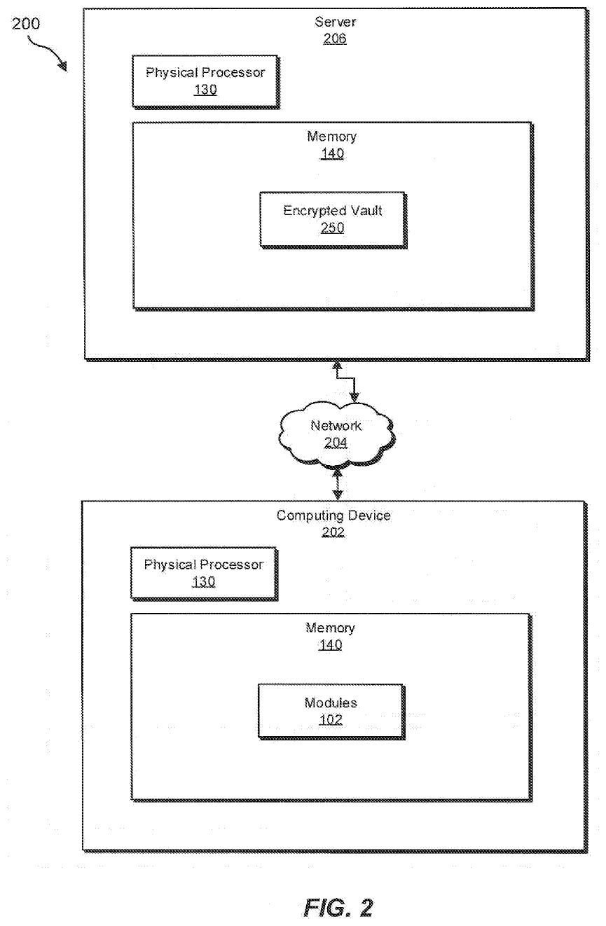

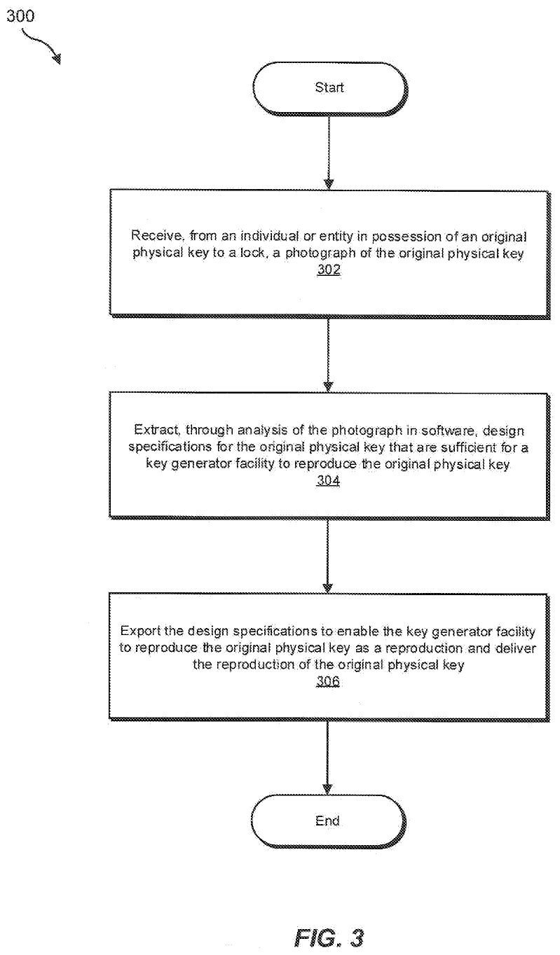

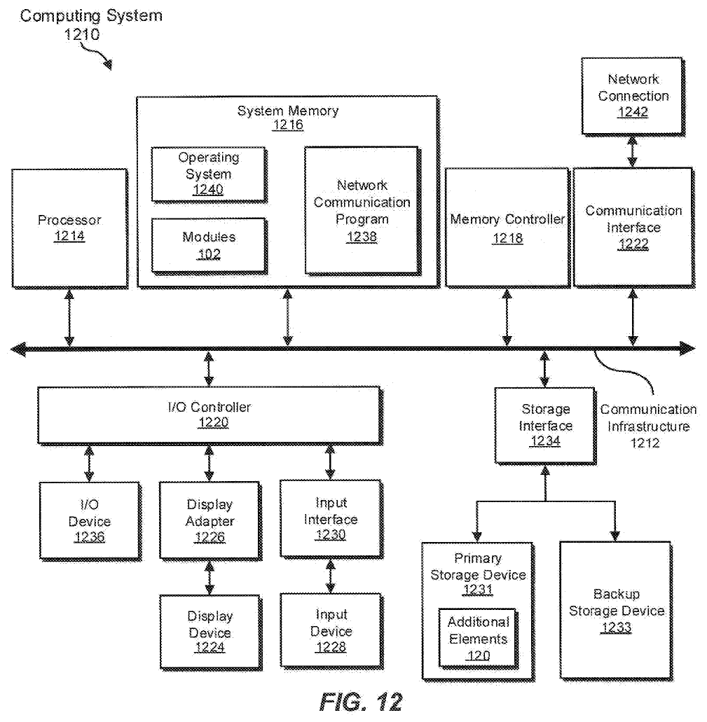

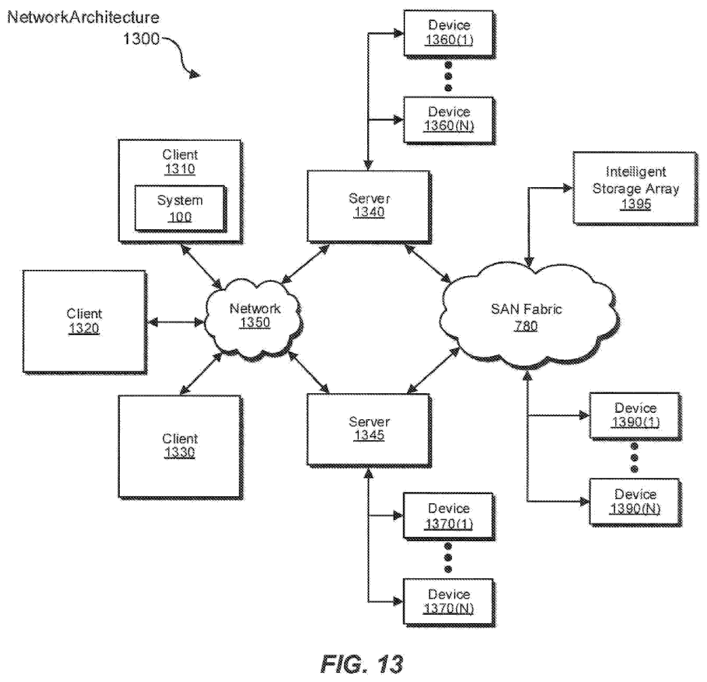

The following will provide, with reference to FIGS. 1-2, detailed descriptions of example systems for providing a virtual locksmith. Detailed descriptions of corresponding computer-implemented methods will also be provided in connection with FIG. 3-11. In addition, detailed descriptions of an example computing system and network architecture capable of implementing one or more of the embodiments described herein will be provided in connection with FIGS. 12 and 13, respectively.

FIG. 1 is a block diagram of example system 100 for providing a virtual locksmith. As illustrated in this figure, example system 100 may include one or more modules 102 for performing one or more tasks. For example, and as will be explained in greater detail below, example system 100 may include a reception module 104 that receives, from an individual or entity in possession of an original physical key to a lock, a photograph of the original physical key. Example system 100 may additionally include an extraction module 106 that extracts, through analysis of the photograph in software, design specifications 122 for the original physical key that are sufficient for a key generator facility to reproduce the original physical key. Example system 100 may also include an exporting module 108 that exports design specifications 122 to enable the key generator facility to reproduce the original physical key as a reproduction and deliver the reproduction of the original physical key. Although illustrated as separate elements, one or more of modules 102 in FIG. 1 may represent portions of a single module or application.

In certain embodiments, one or more of modules 102 in FIG. 1 may represent one or more software applications or programs that, when executed by a computing device, may cause the computing device to perform one or more tasks. For example, and as will be described in greater detail below, one or more of modules 102 may represent modules stored and configured to run on one or more computing devices, such as the devices illustrated in FIG. 2 (e.g., computing device 202 and/or server 206). One or more of modules 102 in FIG. 1 may also represent all or portions of one or more special-purpose computers configured to perform one or more tasks.

As illustrated in FIG. 1, example system 100 may also include one or more memory devices, such as memory 140. Memory 140 generally represents any type or form of volatile or non-volatile storage device or medium capable of storing data and/or computer-readable instructions. In one example, memory 140 may store, load, and/or maintain one or more of modules 102. Examples of memory 140 include, without limitation, Random Access Memory (RAM), Read Only Memory (ROM), flash memory, Hard Disk Drives (HDDs), Solid-State Drives (SSDs), optical disk drives, caches, variations or combinations of one or more of the same, and/or any other suitable storage memory.

As illustrated in FIG. 1, example system 100 may also include one or more physical processors, such as physical processor 130. Physical processor 130 generally represents any type or form of hardware-implemented processing unit capable of interpreting and/or executing computer-readable instructions. In one example, physical processor 130 may access and/or modify one or more of modules 102 stored in memory 140. Additionally or alternatively, physical processor 130 may execute one or more of modules 102 to facilitate providing a virtual locksmith. Examples of physical processor 130 include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, and/or any other suitable physical processor.

Example system 100 in FIG. 1 may be implemented in a variety of ways. For example, all or a portion of example system 100 may represent portions of example system 200 in FIG. 2. As shown in FIG. 2, system 200 may include a computing device 202 in communication with a server 206 via a network 204. In one example, all or a portion of the functionality of modules 102 may be performed by computing device 202, server 206, and/or any other suitable computing system.

For example, and as will be described in greater detail below, reception module 104 may receive, from an individual or entity in possession of an original physical key to a lock, a photograph of the original physical key. Extraction module 106 may extract, through analysis of the photograph in software, design specifications 122 for the original physical key that are sufficient for a key generator facility to reproduce the original physical key. Exporting module 108 may export design specifications 122 to enable the key generator facility to reproduce the original physical key as a reproduction and deliver the reproduction of the original physical key. FIG. 2 also illustrates how computing device 202 may optionally be in network communication with a server 206, which may provide an encrypted vault 250 for storing the photograph and/or the design specifications. The use of encrypted vault 250 may enable the same customer to repeatedly request multiple replacements of the same key based on only a single photograph, without physically transporting the key to a replacement facility, and without repeatedly transmitting different photographs of the original key.

Computing device 202 generally represents any type or form of computing device capable of reading computer-executable instructions. Additional examples of computing device 202 include, without limitation, laptops, tablets, desktops, servers, cellular phones, Personal Digital Assistants (PDAs), multimedia players, embedded systems, wearable devices (e.g., smart watches, smart glasses, etc.), smart vehicles, smart packaging (e.g., active or intelligent packaging), gaming consoles, so-called Internet-of-Things devices (e.g., smart appliances, etc.), variations or combinations of one or more of the same, and/or any other suitable computing device.

Server 206 generally represents any type or form of computing device that is capable of facilitating the performance of method 300 of FIG. 3. Additional examples of server 206 include, without limitation, security servers, application servers, web servers, storage servers, and/or database servers configured to run certain software applications and/or provide various security, web, storage, and/or database services. Although illustrated as a single entity in FIG. 2, server 206 may include and/or represent a plurality of servers that work and/or operate in conjunction with one another.

Network 204 generally represents any medium or architecture capable of facilitating communication or data transfer. In one example, network 204 may facilitate communication between computing device 202 and server 206. In this example, network 204 may facilitate communication or data transfer using wireless and/or wired connections. Examples of network 204 include, without limitation, an intranet, a Wide Area Network (WAN), a Local Area Network (LAN), a Personal Area Network (PAN), the Internet, Power Line Communications (PLC), a cellular network (e.g., a Global System for Mobile Communications (GSM) network), portions of one or more of the same, variations or combinations of one or more of the same, and/or any other suitable network.

FIG. 3 is a flow diagram of an example computer-implemented method 300 for providing a virtual locksmith. The steps shown in FIG. 3 may be performed by any suitable computer-executable code and/or computing system, including system 100 in FIG. 1, system 200 in FIG. 2, and/or variations or combinations of one or more of the same. In one example, each of the steps shown in FIG. 3 may represent an algorithm whose structure includes and/or is represented by multiple sub-steps, examples of which will be provided in greater detail below.

As illustrated in FIG. 3, at step 302, one or more of the systems described herein may receive, from an individual or entity in possession of an original physical key to a lock, a photograph of the original physical key. For example, reception module 104 may, as part of computing device 202 in FIG. 2, receive, from an individual or entity in possession of an original physical key to a lock, a photograph of the original physical key.

Reception module 104 may perform step 302 in a variety of ways. Generally speaking, reception module 104 may receive the photograph of the original physical key through computer input/output operations. For example, a user may insert a peripheral storage device, such as a USB stick, and thereby transmit the photograph into a computing device where reception module 104 may access it. In other examples, a user may transmit the photograph by text message, email, or another network message, such as by uploading to a website through a web interface.

At step 304, one or more of the systems described herein may extract, through analysis of the photograph in software, design specifications for the original physical key that are sufficient for a key generator facility to reproduce the original physical key. For example, extraction module 106 may, as part of computing device 202 in FIG. 2, extract, through analysis of the photograph in software, design specifications for the original physical key that are sufficient for a key generator facility to reproduce the original physical key.

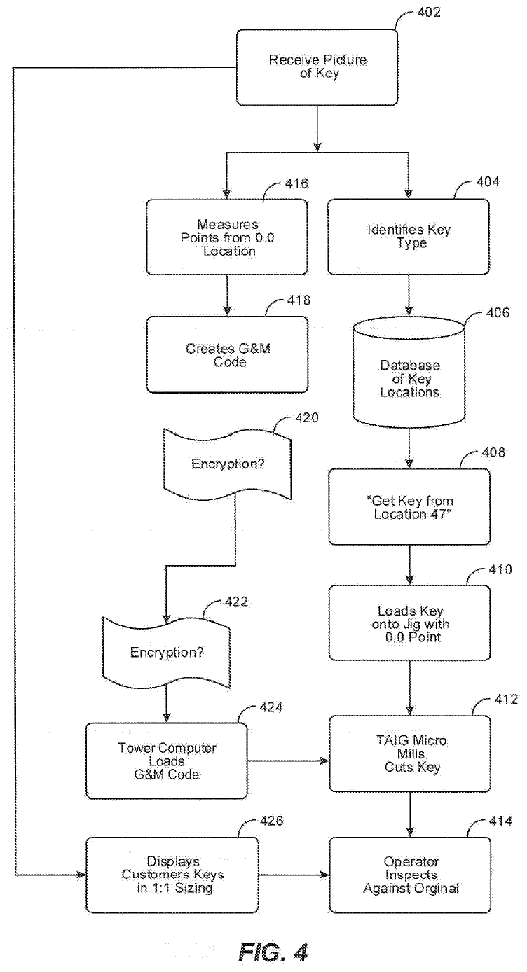

Extraction module 106 may perform step 304 in a variety of ways. For example, extraction module 106 may extract the design specifications at least in part by identifying a type of the original physical key as a KWIKSET type or SCHLAGE type. FIG. 4 provides a more detailed flow diagram that may correspond to one embodiment of method 300. Accordingly, at step 402, which may correspond to step 302 of method 300, the picture of the original physical key may have been received. Subsequently, at step 404, extraction module 104 may begin to extract the design specifications for the key at least in part by identifying a type of the key.

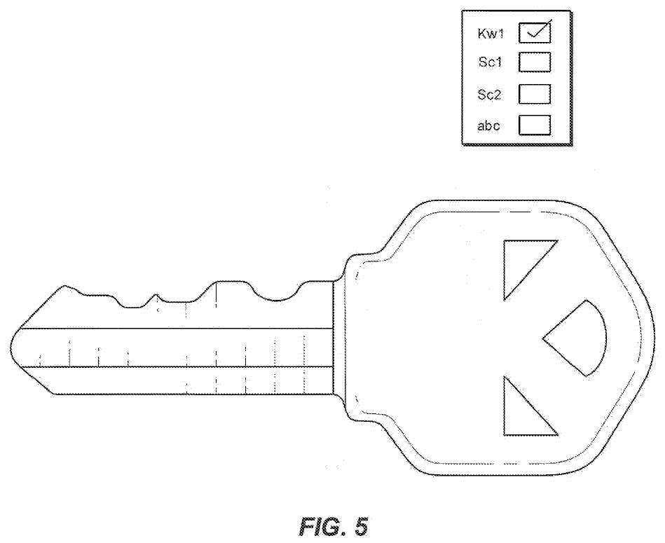

FIG. 5 further shows an example of how the type of the key may be identified, extracted, and/or categorized. As shown in this figure, the option Kw1, for a first type of KWIKSET keys, has been checked, thereby indicating that the particular key shown in the diagram matches this type of key rather than another type. This diagram also lists “Sc1” and “Sc2” as two other options for categorizing the type the key, and these two options may correspond to two types of SCHLAGE key, as is understood by those having skill in the art. Lastly, another option specifies “abc,” which serves as an arbitrary example of additional and hypothetical types of keys that may be identified and extracted at step 304.

As another example, extraction module 106 may also extract the design specifications at least in part by identifying a type of the original physical key as a tumbler key. The diagram of the key shown in FIG. 5 serves as an example of a tumbler key. More specifically, extraction module 106 may categorize the type of the key as a pin tumbler lock key or a wafer tumbler lock key.

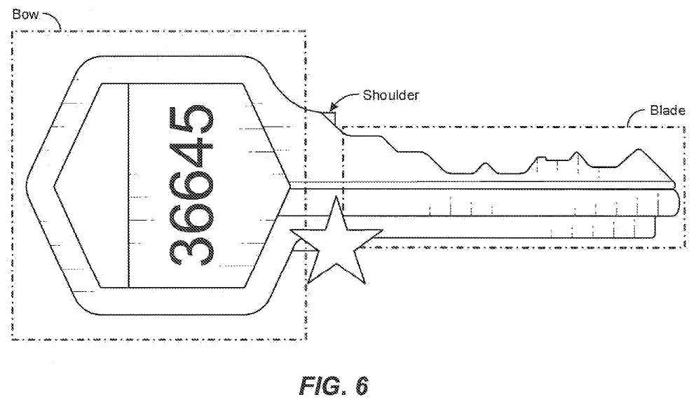

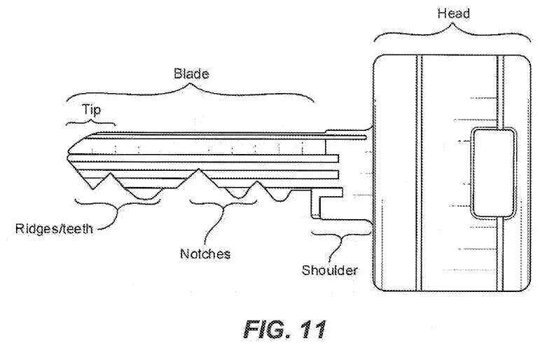

In even further examples, extraction module 106 may extract the design specifications at least in part by identifying a type of the original physical key in terms of the head type of the original physical key or a length of the original physical key. For illustrative purposes, FIG. 11 shows a diagram of an example tumbler key and its subcomponents. Accordingly, the diagram of this figure identifies the “head” portion of the key, and extraction module 106 may optionally identify a type of the head of the key. Similarly, extraction module 106 may identify a length of the key, which may include a total length from the edge of the tip to the edge of the head. Additionally, or alternatively, extraction module 106 may identify a length of any suitable permutation of the total length and/or the various subcomponent lengths, including the length of the head, the length of the blade, the length of the tip, the length of the teeth, the length of the notches, and/or the length of the shoulder, as further shown in this figure. Similarly, FIG. 6 shows another illustrative diagram of an example key, and the subcomponents of the bow, which may roughly correspond to the head, as well as the shoulder and blade.

Returning to FIG. 4, at step 406, extraction module 106 may reference a database of key locations. Extraction module 106 may reference the database in response to identifying a type of the original physical key at step 404, as further discussed above. In response to identifying the type of the key, extraction module 106 may thereby match the type of the original physical key to a particular location within a database of key locations. The specific location within the database of key locations may correspond to a location where a pre-existing key is held that corresponds to the original physical key such that the pre-existing key can be cut to reproduce the original physical key.

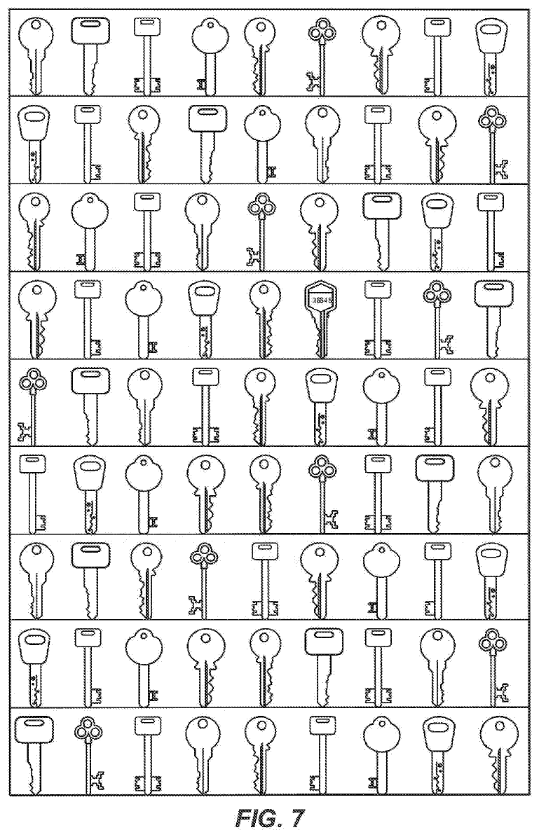

For illustration purposes, FIG. 7 shows an example of inventory of pre-existing keys that may be cut, or further cut, to reproduce the original physical key in accordance with step 406. Although the example of this figure shows keys that may have some teeth already cut into them, these keys may be further cut to match more exactly the original physical key of method 300. Alternatively, in some examples the inventory of pre-existing keys may include no pre-existing teeth and, instead, the pre-existing keys may be cut to create all of the teeth of the original physical key. Thus, in the example of FIG. 4, at step 408 extraction module 106 may command the retrieval of a specific pre-existing key from the inventory shown in FIG. 7.

In further examples, extraction module 106 may extract the design specifications at least in part by measuring a set of teeth locations along an edge of the original physical key. Returning to FIG. 11, this figure shows a diagram of where the ridges or teeth may be located on the original physical key. Extraction module 106 may extract information identifying an angle, height, length, and/or orientation or other information describing the nature and shape of the ridges and teeth. In some examples, extraction module 106 may extract information identifying every tooth along the edge of the original physical key.

In additional examples, extraction module 106 may measure the set of teeth locations at least in part by establishing coordinates that locate the respective teeth locations as two-dimensional offsets from a (0, 0) point on a two-dimensional plane. In the example of FIG. 11, the key is shown as lying flat on the page of the figure, where the page of the figure corresponds to the two-dimensional plane along which the two-dimensional coordinates may be measured.

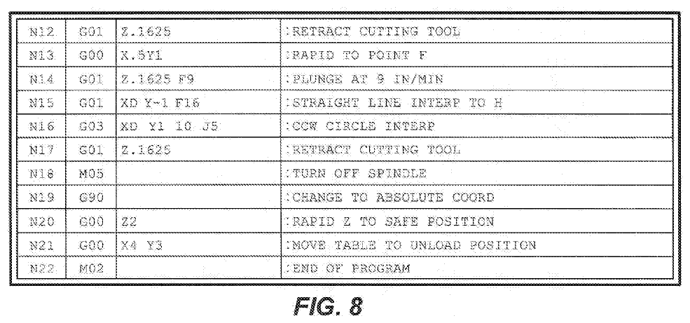

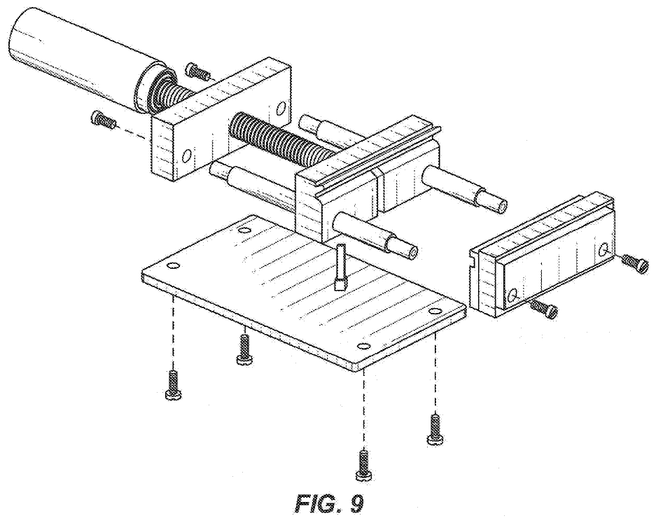

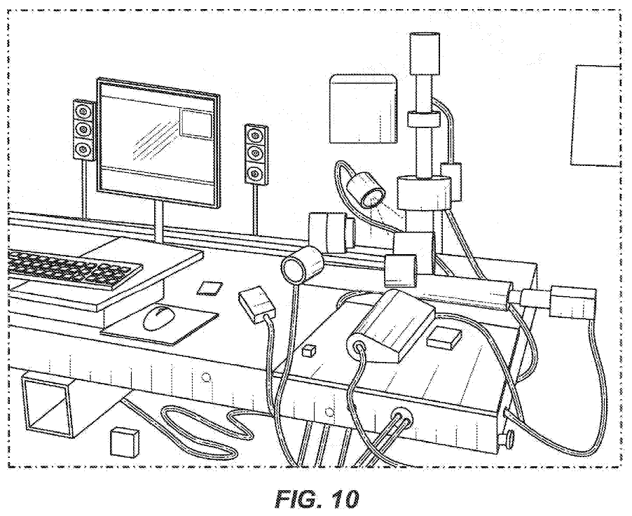

Extraction module 106 may extract the two-dimensional coordinates for the teeth of the key to enable a micro mill to reproduce the teeth of the key when a pre-existing key has been loaded appropriately onto a jig. Furthermore, FIG. 9 shows an illustrative diagram of such a jig. Similarly, FIG. 10 shows an illustrative example of a micro mill. In other words, the two-dimensional offsets from the (0, 0) point on the two-dimensional plane may inform a micro mill how to cut the preexisting key when the preexisting key is loaded onto a jig in relation to a (0, 0) point on the jig such that the original physical key is reproduced. In the example of FIG. 4, extraction module 106 may measure the points identifying the physical structure of the key in reference to the (0, 0) location at step 418. Subsequently, at step 418, extraction module 106 may create or identify a corresponding GM code that matches sufficiently the measurements obtained at step 416. Returning to the example of FIG. 4, at step 410 extraction module 106 may load the pre-existing key that was selected from the inventory onto the jig with reference to the (0, 0) point. Subsequently, at step 412, the micro mill (e.g., a TAIG micro mill) may cut the key according to the design specifications. FIG. 8 shows an illustrative example of computer code that may be executed to operate the micro mill according to the method of FIG. 4.

At step 418, extraction module 106 may optionally extract the design specifications at least in part by extracting a GM code that identifies a preexisting key that can be cut to create the replacement of the original physical key. Extraction module 106 may also optionally encrypt the GM code at steps 420 and 422, and subsequently at step 424, extraction module 106 may load the extracted GM code into a tower computer or other computer for operating the micro mill.

At step 306, one or more of the systems described herein may export the design specifications to enable the key generator facility to reproduce the original physical key as a reproduction and deliver the reproduction of the original physical key. For example, exporting module 108 may, as part of computing device 202 in FIG. 2, export design specifications 122 to enable the key generator facility to reproduce the original physical key as a reproduction and deliver the reproduction of the original physical key.

Exporting module 108 may perform step 306 in a variety of ways. Generally speaking, exporting module 108 may perform step 306 in any suitable manner that facilitates the reproduction and/or the delivery of the reproduction of the original physical key, without the inconvenience of the user previously transporting the original physical key to a key reproduction facility and, instead, allowing the user to simply transmit a photograph, as discussed above. For example, although the steps of method 300 focus on computer or software-enabled functionality, these steps may also be performed in coordination with one or more employees, administrators, and/or key reproduction team members, for example. Thus, after the software has performed method 300, another individual, organization, or other entity may obtain the reproduction of the original physical key and take measures to ensure that the reproduction is made available to the customer (e.g., if the user chooses to travel to the key reproduction facility to retrieve the reproduction) and/or ensure that the reproduction is successfully delivered to the customer, which may be even more convenient due to the fact that, in this scenario, the user is never required to travel to the key reproduction facility or elsewhere.

Thus, in addition to steps 302-306, as discussed above, method 300 may also include additional steps, which may be performed by an autonomous computing device or robot, a human being, and/or any suitable combination thereof. These steps may include the key generator facility reproducing the original physical key and/or the key generator facility delivering the reproduction of the original physical key to the individual or entity.

Returning to FIG. 4, at step 426, the replacement may be displayed sufficiently adjacent the photograph of the original physical key according to a 1:1 sizing ratio to enable a comparison. The comparison may be performed in software and/or by a human operator. The software and/or human operator may perform a visual inspection, at step 414, to ensure that the replacement sufficiently matches the photograph of the original physical key.

FIG. 12 is a block diagram of an example computing system 1210 capable of implementing one or more of the embodiments described and/or illustrated herein. For example, all or a portion of computing system 1210 may perform and/or be a means for performing, either alone or in combination with other elements, one or more of the steps described herein (such as one or more of the steps illustrated in FIG. 3). All or a portion of computing system 1210 may also perform and/or be a means for performing any other steps, methods, or processes described and/or illustrated herein.

Computing system 1210 broadly represents any single or multi-processor computing device or system capable of executing computer-readable instructions. Examples of computing system 1210 include, without limitation, workstations, laptops, client-side terminals, servers, distributed computing systems, handheld devices, or any other computing system or device. In its most basic configuration, computing system 1210 may include at least one processor 1214 and a system memory 1216.

Processor 1214 generally represents any type or form of physical processing unit (e.g., a hardware-implemented central processing unit) capable of processing data or interpreting and executing instructions. In certain embodiments, processor 1214 may receive instructions from a software application or module. These instructions may cause processor 1214 to perform the functions of one or more of the example embodiments described and/or illustrated herein.

System memory 1216 generally represents any type or form of volatile or non-volatile storage device or medium capable of storing data and/or other computer-readable instructions. Examples of system memory 1216 include, without limitation, Random Access Memory (RAM), Read Only Memory (ROM), flash memory, or any other suitable memory device. Although not required, in certain embodiments computing system 1210 may include both a volatile memory unit (such as, for example, system memory 1216) and a non-volatile storage device (such as, for example, primary storage device 1232, as described in detail below). In one example, one or more of modules 102 from FIG. 1 may be loaded into system memory 1216.

In some examples, system memory 1216 may store and/or load an operating system 1240 for execution by processor 1214. In one example, operating system 1240 may include and/or represent software that manages computer hardware and software resources and/or provides common services to computer programs and/or applications on computing system 1210. Examples of operating system 1240 include, without limitation, LINUX, JUNOS, MICROSOFT WINDOWS, WINDOWS MOBILE, MAC OS, APPLE'S 10S, UNIX, GOOGLE CHROME OS, GOOGLE'S ANDROID, SOLARIS, variations of one or more of the same, and/or any other suitable operating system.

In certain embodiments, example computing system 1210 may also include one or more components or elements in addition to processor 1214 and system memory 1216. For example, as illustrated in FIG. 12, computing system 1210 may include a memory controller 1218, an Input/Output (I/O) controller 1220, and a communication interface 1222, each of which may be interconnected via a communication infrastructure 1212. Communication infrastructure 1212 generally represents any type or form of infrastructure capable of facilitating communication between one or more components of a computing device. Examples of communication infrastructure 1212 include, without limitation, a communication bus (such as an Industry Standard Architecture (ISA), Peripheral Component Interconnect (PCI), PCI Express (PCIe), or similar bus) and a network.

Memory controller 1218 generally represents any type or form of device capable of handling memory or data or controlling communication between one or more components of computing system 1210. For example, in certain embodiments memory controller 1218 may control communication between processor 1214, system memory 1216, and I/O controller 1220 via communication infrastructure 1212.

I/O controller 1220 generally represents any type or form of module capable of coordinating and/or controlling the input and output functions of a computing device. For example, in certain embodiments I/O controller 1220 may control or facilitate transfer of data between one or more elements of computing system 1210, such as processor 1214, system memory 1216, communication interface 1222, display adapter 1226, input interface 1230, and storage interface 1234.

As illustrated in FIG. 12, computing system 1210 may also include at least one display device 1224 coupled to I/O controller 1220 via a display adapter 1226. Display device 1224 generally represents any type or form of device capable of visually displaying information forwarded by display adapter 1226. Similarly, display adapter 1226 generally represents any type or form of device configured to forward graphics, text, and other data from communication infrastructure 1212 (or from a frame buffer, as known in the art) for display on display device 1224.

As illustrated in FIG. 12, example computing system 1210 may also include at least one input device 1228 coupled to I/O controller 1220 via an input interface 1230. Input device 1228 generally represents any type or form of input device capable of providing input, either computer or human generated, to example computing system 1210. Examples of input device 1228 include, without limitation, a keyboard, a pointing device, a speech recognition device, variations or combinations of one or more of the same, and/or any other input device.

Additionally or alternatively, example computing system 1210 may include additional I/O devices. For example, example computing system 1210 may include I/O device 1236. In this example, I/O device 1236 may include and/or represent a user interface that facilitates human interaction with computing system 1210. Examples of I/O device 1236 include, without limitation, a computer mouse, a keyboard, a monitor, a printer, a modem, a camera, a scanner, a microphone, a touchscreen device, variations or combinations of one or more of the same, and/or any other I/O device.

Communication interface 1222 broadly represents any type or form of communication device or adapter capable of facilitating communication between example computing system 1210 and one or more additional devices. For example, in certain embodiments communication interface 1222 may facilitate communication between computing system 1210 and a private or public network including additional computing systems. Examples of communication interface 1222 include, without limitation, a wired network interface (such as a network interface card), a wireless network interface (such as a wireless network interface card), a modem, and any other suitable interface. In at least one embodiment, communication interface 1222 may provide a direct connection to a remote server via a direct link to a network, such as the Internet. Communication interface 1222 may also indirectly provide such a connection through, for example, a local area network (such as an Ethernet network), a personal area network, a telephone or cable network, a cellular telephone connection, a satellite data connection, or any other suitable connection.

In certain embodiments, communication interface 1222 may also represent a host adapter configured to facilitate communication between computing system 1210 and one or more additional network or storage devices via an external bus or communications channel. Examples of host adapters include, without limitation, Small Computer System Interface (SCSI) host adapters, Universal Serial Bus (USB) host adapters, Institute of Electrical and Electronics Engineers (IEEE) 1394 host adapters, Advanced Technology Attachment (ATA), Parallel ATA (PATA), Serial ATA (SATA), and External SATA (eSATA) host adapters, Fibre Channel interface adapters, Ethernet adapters, or the like. Communication interface 1222 may also allow computing system 1210 to engage in distributed or remote computing. For example, communication interface 1222 may receive instructions from a remote device or send instructions to a remote device for execution.

In some examples, system memory 1216 may store and/or load a network communication program 1238 for execution by processor 1214. In one example, network communication program 1238 may include and/or represent software that enables computing system 1210 to establish a network connection 1242 with another computing system (not illustrated in FIG. 12) and/or communicate with the other computing system by way of communication interface 1222. In this example, network communication program 1238 may direct the flow of outgoing traffic that is sent to the other computing system via network connection 1242. Additionally or alternatively, network communication program 1238 may direct the processing of incoming traffic that is received from the other computing system via network connection 1242 in connection with processor 1214.

Although not illustrated in this way in FIG. 12, network communication program 1238 may alternatively be stored and/or loaded in communication interface 1222. For example, network communication program 1238 may include and/or represent at least a portion of software and/or firmware that is executed by a processor and/or Application Specific Integrated Circuit (ASIC) incorporated in communication interface 1222.

As illustrated in FIG. 12, example computing system 1210 may also include a primary storage device 1232 and a backup storage device 1233 coupled to communication infrastructure 1212 via a storage interface 1234. Storage devices 1232 and 1233 generally represent any type or form of storage device or medium capable of storing data and/or other computer-readable instructions. For example, storage devices 1232 and 1233 may be a magnetic disk drive (e.g., a so-called hard drive), a solid state drive, a floppy disk drive, a magnetic tape drive, an optical disk drive, a flash drive, or the like. Storage interface 1234 generally represents any type or form of interface or device for transferring data between storage devices 1232 and 1233 and other components of computing system 1210.

In certain embodiments, storage devices 1232 and 1233 may be configured to read from and/or write to a removable storage unit configured to store computer software, data, or other computer-readable information. Examples of suitable removable storage units include, without limitation, a floppy disk, a magnetic tape, an optical disk, a flash memory device, or the like. Storage devices 1232 and 1233 may also include other similar structures or devices for allowing computer software, data, or other computer-readable instructions to be loaded into computing system 1210. For example, storage devices 1232 and 1233 may be configured to read and write software, data, or other computer-readable information. Storage devices 1232 and 1233 may also be a part of computing system 1210 or may be a separate device accessed through other interface systems.

Many other devices or subsystems may be connected to computing system 1210. Conversely, all of the components and devices illustrated in FIG. 12 need not be present to practice the embodiments described and/or illustrated herein. The devices and subsystems referenced above may also be interconnected in different ways from that shown in FIG. 12. Computing system 1210 may also employ any number of software, firmware, and/or hardware configurations. For example, one or more of the example embodiments disclosed herein may be encoded as a computer program (also referred to as computer software, software applications, computer-readable instructions, or computer control logic) on a computer-readable medium. The term “computer-readable medium,” as used herein, generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The computer-readable medium containing the computer program may be loaded into computing system 1210. All or a portion of the computer program stored on the computer-readable medium may then be stored in system memory 1216 and/or various portions of storage devices 1232 and 1233. When executed by processor 1214, a computer program loaded into computing system 1210 may cause processor 1214 to perform and/or be a means for performing the functions of one or more of the example embodiments described and/or illustrated herein. Additionally or alternatively, one or more of the example embodiments described and/or illustrated herein may be implemented in firmware and/or hardware. For example, computing system 1210 may be configured as an Application Specific Integrated Circuit (ASIC) adapted to implement one or more of the example embodiments disclosed herein.

FIG. 13 is a block diagram of an example network architecture 1300 in which client systems 1310, 1320, and 1330 and servers 1340 and 1345 may be coupled to a network 1350. As detailed above, all or a portion of network architecture 1300 may perform and/or be a means for performing, either alone or in combination with other elements, one or more of the steps disclosed herein (such as one or more of the steps illustrated in FIG. 3). All or a portion of network architecture 1300 may also be used to perform and/or be a means for performing other steps and features set forth in the present disclosure.

Client systems 1310, 1320, and 1330 generally represent any type or form of computing device or system, such as example computing system 1210 in FIG. 12. Similarly, servers 1340 and 1345 generally represent computing devices or systems, such as application servers or database servers, configured to provide various database services and/or run certain software applications. Network 1350 generally represents any telecommunication or computer network including, for example, an intranet, a WAN, a LAN, a PAN, or the Internet. In one example, client systems 1310, 1320, and/or 1330 and/or servers 1340 and/or 1345 may include all or a portion of system 100 from FIG. 1.

As illustrated in FIG. 13, one or more storage devices 1360(1)-(N) may be directly attached to server 1340. Similarly, one or more storage devices 1370(1)-(N) may be directly attached to server 1345. Storage devices 1360(1)-(N) and storage devices 1370(1)-(N) generally represent any type or form of storage device or medium capable of storing data and/or other computer-readable instructions. In certain embodiments, storage devices 1360(1)-(N) and storage devices 1370(1)-(N) may represent Network-Attached Storage (NAS) devices configured to communicate with servers 1340 and 1345 using various protocols, such as Network File System (NFS), Server Message Block (SMB), or Common Internet File System (CIFS).

Servers 1340 and 1345 may also be connected to a Storage Area Network (SAN) fabric 1380. SAN fabric 1380 generally represents any type or form of computer network or architecture capable of facilitating communication between a plurality of storage devices. SAN fabric 1380 may facilitate communication between servers 1340 and 1345 and a plurality of storage devices 1390(1)-(N) and/or an intelligent storage array 1395. SAN fabric 1380 may also facilitate, via network 1350 and servers 1340 and 1345, communication between client systems 1310, 1320, and 1330 and storage devices 1390(1)-(N) and/or intelligent storage array 1395 in such a manner that devices 1390(1)-(N) and array 1395 appear as locally attached devices to client systems 1310, 1320, and 1330. As with storage devices 1360(1)-(N) and storage devices 1370(1)-(N), storage devices 1390(1)-(N) and intelligent storage array 1395 generally represent any type or form of storage device or medium capable of storing data and/or other computer-readable instructions.

In certain embodiments, and with reference to example computing system 1210 of FIG. 12, a communication interface, such as communication interface 1222 in FIG. 12, may be used to provide connectivity between each client system 1310, 1320, and 1330 and network 1350. Client systems 1310, 1320, and 1330 may be able to access information on server 1340 or 1345 using, for example, a web browser or other client software. Such software may allow client systems 1310, 1320, and 1330 to access data hosted by server 1340, server 1345, storage devices 1360(1)-(N), storage devices 1370(1)-(N), storage devices 1390(1)-(N), or intelligent storage array 1395. Although FIG. 13 depicts the use of a network (such as the Internet) for exchanging data, the embodiments described and/or illustrated herein are not limited to the Internet or any particular network-based environment.

In at least one embodiment, all or a portion of one or more of the example embodiments disclosed herein may be encoded as a computer program and loaded onto and executed by server 1340, server 1345, storage devices 1360(1)-(N), storage devices 1370(1)-(N), storage devices 1390(1)-(N), intelligent storage array 1395, or any combination thereof. All or a portion of one or more of the example embodiments disclosed herein may also be encoded as a computer program, stored in server 1340, run by server 1345, and distributed to client systems 1310, 1320, and 1330 over network 1350.

As detailed above, computing system 1210 and/or one or more components of network architecture 1300 may perform and/or be a means for performing, either alone or in combination with other elements, one or more steps of an example method for providing a virtual locksmith.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered example in nature since many other architectures can be implemented to achieve the same functionality.

In some examples, all or a portion of example system 100 in FIG. 1 may represent portions of a cloud-computing or network-based environment. Cloud-computing environments may provide various services and applications via the Internet. These cloud-based services (e.g., software as a service, platform as a service, infrastructure as a service, etc.) may be accessible through a web browser or other remote interface. Various functions described herein may be provided through a remote desktop environment or any other cloud-based computing environment.

In various embodiments, all or a portion of example system 100 in FIG. 1 may facilitate multi-tenancy within a cloud-based computing environment. In other words, the software modules described herein may configure a computing system (e.g., a server) to facilitate multi-tenancy for one or more of the functions described herein. For example, one or more of the software modules described herein may program a server to enable two or more clients (e.g., customers) to share an application that is running on the server. A server programmed in this manner may share an application, operating system, processing system, and/or storage system among multiple customers (i.e., tenants). One or more of the modules described herein may also partition data and/or configuration information of a multi-tenant application for each customer such that one customer cannot access data and/or configuration information of another customer.

According to various embodiments, all or a portion of example system 100 in FIG. 1 may be implemented within a virtual environment. For example, the modules and/or data described herein may reside and/or execute within a virtual machine. As used herein, the term “virtual machine” generally refers to any operating system environment that is abstracted from computing hardware by a virtual machine manager (e.g., a hypervisor). Additionally or alternatively, the modules and/or data described herein may reside and/or execute within a virtualization layer. As used herein, the term “virtualization layer” generally refers to any data layer and/or application layer that overlays and/or is abstracted from an operating system environment. A virtualization layer may be managed by a software virtualization solution (e.g., a file system filter) that presents the virtualization layer as though it were part of an underlying base operating system. For example, a software virtualization solution may redirect calls that are initially directed to locations within a base file system and/or registry to locations within a virtualization layer.

In some examples, all or a portion of example system 100 in FIG. 1 may represent portions of a mobile computing environment. Mobile computing environments may be implemented by a wide range of mobile computing devices, including mobile phones, tablet computers, e-book readers, personal digital assistants, wearable computing devices (e.g., computing devices with a head-mounted display, smartwatches, etc.), and the like. In some examples, mobile computing environments may have one or more distinct features, including, for example, reliance on battery power, presenting only one foreground application at any given time, remote management features, touchscreen features, location and movement data (e.g., provided by Global Positioning Systems, gyroscopes, accelerometers, etc.), restricted platforms that restrict modifications to system-level configurations and/or that limit the ability of third-party software to inspect the behavior of other applications, controls to restrict the installation of applications (e.g., to only originate from approved application stores), etc. Various functions described herein may be provided for a mobile computing environment and/or may interact with a mobile computing environment.

In addition, all or a portion of example system 100 in FIG. 1 may represent portions of, interact with, consume data produced by, and/or produce data consumed by one or more systems for information management. As used herein, the term “information management” may refer to the protection, organization, and/or storage of data. Examples of systems for information management may include, without limitation, storage systems, backup systems, archival systems, replication systems, high availability systems, data search systems, virtualization systems, and the like.

In some embodiments, all or a portion of example system 100 in FIG. 1 may represent portions of, produce data protected by, and/or communicate with one or more systems for information security. As used herein, the term “information security” may refer to the control of access to protected data. Examples of systems for information security may include, without limitation, systems providing managed security services, data loss prevention systems, identity authentication systems, access control systems, encryption systems, policy compliance systems, intrusion detection and prevention systems, electronic discovery systems, and the like.

According to some examples, all or a portion of example system 100 in FIG. 1 may represent portions of, communicate with, and/or receive protection from one or more systems for endpoint security. As used herein, the term “endpoint security” may refer to the protection of endpoint systems from unauthorized and/or illegitimate use, access, and/or control. Examples of systems for endpoint protection may include, without limitation, anti-malware systems, user authentication systems, encryption systems, privacy systems, spam-filtering services, and the like.

The process parameters and sequence of steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

While various embodiments have been described and/or illustrated herein in the context of fully functional computing systems, one or more of these example embodiments may be distributed as a program product in a variety of forms, regardless of the particular type of computer-readable media used to actually carry out the distribution. The embodiments disclosed herein may also be implemented using software modules that perform certain tasks. These software modules may include script, batch, or other executable files that may be stored on a computer-readable storage medium or in a computing system. In some embodiments, these software modules may configure a computing system to perform one or more of the example embodiments disclosed herein.

In addition, one or more of the modules described herein may transform data, physical devices, and/or representations of physical devices from one form to another. Additionally or alternatively, one or more of the modules recited herein may transform a processor, volatile memory, non-volatile memory, and/or any other portion of a physical computing device from one form to another by executing on the computing device, storing data on the computing device, and/or otherwise interacting with the computing device.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A computer-implemented method for providing a virtual locksmith, at least a portion of the method being performed by a computing device comprising at least one processor, the method comprising:
receiving a photograph of an original physical key;
extracting, through analysis of the photograph in software, design specifications for the original physical key that are sufficient for a key generator facility to reproduce the original physical key; and
exporting the design specifications to enable the key generator facility to reproduce the original physical key as a reproduction and deliver the reproduction of the original physical key.

2. The computer-implemented method of claim 1, further comprising the key generator facility reproducing the original physical key.

3. The computer-implemented method of claim 2, further comprising the key generator facility delivering the reproduction of the original physical key to the individual or entity.

4. The computer-implemented method of claim 1, wherein extracting, through analysis of the photograph in software, the design specifications comprises identifying a type of the original physical key in terms of the head type of the original physical key or a length of the original physical key.

5. The computer-implemented method of claim 4, wherein extracting, through analysis of the photograph in software, the design specifications comprises identifying a location within a database of key locations where the location holds a preexisting key that corresponds to the original physical key such that the preexisting key can be cut to reproduce the original physical key.

6. The computer-implemented method of claim 4, wherein extracting, through analysis of the photograph in software, the design specifications comprises measuring a set of teeth locations along an edge of the original physical key.

7. The computer-implemented method of claim 6, wherein the set of teeth locations comprises every tooth along the edge of the original physical key.

8. The computer-implemented method of claim 6, wherein measuring the set of teeth locations comprises establishing coordinates that locate the respective teeth locations as two-dimensional offsets from a (0, 0) point on a two-dimensional plane.

9. The computer-implemented method of claim 8, wherein the two-dimensional offsets from the (0, 0) point on the two-dimensional plane inform a micro mill how to cut the preexisting key when the preexisting key is loaded onto a jig in relation to a (0, 0) point on the jig such that the original physical key is reproduced.

10. The computer-implemented method of claim 4, wherein extracting, through analysis of the photograph in software, the design specifications comprises extracting a GM code that identifies a preexisting key that can be cut to create the replacement of the original physical key.

11. The computer-implemented method of claim 10, further comprising encrypting the GM code.

12. The computer-implemented method of claim 10, further comprising transmitting the GM code to a tower computer that loads the GM code to enable a micro mill to cut the pre-existing key that matches the GM code.

13. The computer-implemented method of claim 1, further comprising displaying the replacement sufficiently adjacent the photograph of the original physical key according to a 1:1 sizing ratio to enable a comparison

14. The computer-implemented method of claim 13, further comprising performing a visual inspection to ensure that the replacement sufficiently matches the photograph of the original physical key.

15. The computer-implemented method of claim 1, further comprising storing a copy of the design specifications within an encrypted vault to enable the individual or entity to subsequently reuse the design specifications without providing an additional photograph of the original physical key or the replacement.

16. The computer-implemented method of claim 1, wherein performing the method eliminates a requirement for the individual or entity to physically deliver the original physical key to the key generator facility in order to generate the replacement.

17. The computer-implemented method of claim 1, wherein extracting, through analysis of the photograph in software, the design specifications comprises identifying a type of the original physical key as a KWIKSET type or SCHLAGE type.

18. The computer-implemented method of claim 1, wherein extracting, through analysis of the photograph in software, the design specifications comprises identifying a type of the original physical key as a pin tumbler lock key or a wafer tumbler lock key.

19. A system for providing a virtual locksmith, the system comprising:
a reception module, stored in memory, that receives a photograph of an original physical key;
an extraction module, stored in memory, that extracts, through analysis of the photograph in software, design specifications for the original physical key that are sufficient for a key generator facility to reproduce the original physical key;
an exporting module, stored in memory, that exports the design specifications to enable the key generator facility to reproduce the original physical key as a reproduction and deliver the reproduction of the original physical key; and
at least one physical processor configured to execute the reception module, the extraction module, and the exporting module.

20. A non-transitory computer-readable medium comprising one or more computer-readable instructions that, when executed by at least one processor of a computing device, cause the computing device to:
receive a photograph of the original physical key;
extract, through analysis of the photograph in software, design specifications for the original physical key that are sufficient for a key generator facility to reproduce the original physical key; and
export the design specifications to enable the key generator facility to reproduce the original physical key as a reproduction and deliver the reproduction of the original physical key.
